(19) United States
(12) Patent Application Publication
(10) Pub. No.: US 2019/0326460 A1
(43) Pub. Date: Oct. 24, 2019

(54) Micro-Grid Luminescent Solar Concentrators and Related Methods of Manufacturing

(71) Applicants: California Institute of Technology, Pasadena, CA (US); The Regents of the University of California, Oakland, CA (US); The Board of Trustees of the University of Illinois, Urbana, IL (US)

(72) Inventors: David R. Needell, Pasadena, CA (US); Haley Bauser, Pasadena, CA (US); Harry A. Atwater, South Pasadena, CA (US); Armand P. Alivisatos, Berkeley, CA (US); Ralph Nuzzo, Champaign, IL (US); Ognjen Ilic, Pasadena, CA (US); Colton Bukowsky, Pasadena, CA (US); Brent A. Koscher, Berkeley, CA (US); Megan Phelan, Pasadena, CA (US)

(73) Assignees: California Institute of Technology, Pasadena, CA (US); The Regents of the University of California, Oakland, CA (US); The Board of Trustees of the University of Illinois, Urbana, IL (US)

(21) Appl. No.: 16/390,789

(22) Filed: Apr. 22, 2019

Related U.S. Application Data
(60) Provisional application No. 62/660,455, filed on Apr. 20, 2018.

(51) Int. Cl. H01L 31/055; H01L 31/054; H01L 31/0475; H01L 31/0216

(52) U.S. Cl. CPC H01L 31/055; H01L 31/02162; H01L 31/0475; H01L 31/0543

(57) ABSTRACT

Luminescent solar concentrators having a grid-based PV design can be implemented in many different ways. In several embodiments, the LSC is implemented using infrared luminophore technology combined with a PV design implementing a grid of PV cells. LSCs can incorporate quantum dots that absorb uniformly across the visible spectrum and photoluminesce down-shifted energy light in the infrared wavelength regime. Some embodiments include PV cells utilizing micro-grid structures that can be implemented for scalable and controllably transparent applications, such as but not limited to power windows targeted for building integrated photovoltaic applications. In a number of embodiments, the LSCs can utilize a unique PV cell form factor and spectral filter coatings to increase the thermal insulation of the window and enhance photocurrent capture by a silicon micro-grid.

### CROSS-REFERENCE TO RELATED APPLICATIONS

The current application claims the benefit of and priority under 35 U.S.C. § 119(e) to U.S. Provisional Patent Application No. 62/660,455 entitled “Luminescent Solar Concentrator Micro-Grid Power Window,” filed Apr. 20, 2018. The disclosure of U.S. Provisional Patent Application No. 62/660,455 is hereby incorporated by reference in its entirety for all purposes.

### FIELD OF THE INVENTION

The present invention generally relates to luminescent solar concentrators and, more specifically, to micro-grid luminescent solar concentrators.

### BACKGROUND

Silicon photovoltaic (Si-PV) modules currently dominate the solar energy market. Increased progress into Si-PV efficiency enhancements combined with historically low module costs aim to decrease the overall Levelized Cost of Electricity (LCOE) to a point competitive with non-renewable energy sources. Despite recent LCOE reductions, Si-PV technology remains economically inferior to fossil fuels. Additionally, flat-plate Si solar modules generally require geographical locations with high direct normal incidence (DNI) sunlight conditions in order to maintain module performance. Both the strict DNI requirement and the high LCOE of Si-PV cells ultimately limit the dissemination of solar power into the global energy market.

A solution for reducing expensive cell area includes the use of PV optical concentrators, which can be referred to as devices for concentrating electromagnetic radiation for the purposes of generating electricity. A PV concentrator typically includes materials designed to gather incoming radiation from an input area and redirect the gathered radiation to an output area. If the effective input area is larger than the effective output area, the output can theoretically result in a higher irradiance than the input and, subsequently, require less expensive PV material. A concentration factor can then be defined as the ratio between the output and input irradiance of the whole device. However, some of the gathered light may not be useable due to losses from absorption and escaped light and, as is the case with geometric concentrators, light that occupies angles outside the acceptance angle. As such, an efficiency metric of optical concentrators can be defined as the ratio of the incoming radiant flux and the outgoing flux—i.e., the fraction of incoming energy that the device can deliver as usable output energy.

One class of optical concentrators includes luminescent solar concentrators (“LSCs”). A traditional LSC can include an optical waveguide with luminophores suspended in a polymer matrix and photovoltaic (PV) material lining the edge(s) of the waveguide. In such devices, both diffuse and direct sunlight incident upon the waveguide can be absorbed by the embedded luminophores as the acceptance angle of such LSCs extends across the entire incident photon hemisphere. If not non-radiatively absorbed by the luminophore, the absorbed photons can photoluminesce at longer wavelengths. Total internal reflection (TIR) can be utilized to guide the re-emitted photons to the edge(s) of the waveguide, thereby impinging upon the PV cells. Concentration of light is directly proportional to the geometric gain (GG) of the LSC—defined as the ratio of waveguide illumination area to total PV cell area. Luminescent solar concentrators have garnered interest due to their ability to utilize diffuse light and their potential for use in architectural applications such as large area power-generating windows. However, LSCs have not yet reached commercialization for photovoltaic power generation, largely due to their comparatively low power conversion efficiencies (PCEs) and lack of scalability.

### SUMMARY OF THE INVENTION

One embodiment includes a luminescent solar concentrator including a waveguide layer configured to couple incident light, a plurality of luminophores configured to absorb incident light and emit infrared light within the waveguide layer, a plurality of photovoltaic cells configured to convert incident light traveling within the waveguide into a voltage signal, wherein the photovoltaic cells are interconnected in a grid pattern.

In another embodiment, each of the plurality of photovoltaic cells has dimensions of less than 1000 micrometers.

In a further embodiment, the plurality of luminophores is configured to absorb greater than 40% of the amount of light having wavelengths between 400 nm and 700 nm.

In still another embodiment, the waveguide layer includes a material selected from the group consisting of: poly(lauryl methacrylate), poly(methyl methacrylate, polydimethylsiloxane, and polymides.

In a still further embodiment, the plurality of luminophores includes a plurality of quantum dots.

In yet another embodiment, each of the plurality of quantum dots includes a core/shell structure.

In a yet further embodiment, the plurality of luminophores includes a quantum dot selected from the group of: an InAs/InP/ZnSe quantum dot, a CdSe/CdS quantum dot, and a CuInS₂/ZnS quantum dot.

In another additional embodiment, the plurality of photovoltaic cells includes a photovoltaic cell selected from the group of: a passivated emitter rear contact cell, a heterojunction with intrinsic thin layer Si cell, a passivated contact Si cell, GaAs cell, and InGaP cell.

In a further additional embodiment, the plurality of photovoltaic cells is interconnected with a material selected from the group of: Au, Ag, Cu, Al, and chrome.

In another embodiment again, the luminescent solar concentrator further includes a first filter component disposed on a first side of the waveguide layer and a second filter component disposed on a second side of the waveguide layer.

In a further embodiment again, the first filter component includes a filter selected from the group of: a high-pass filter, a high-contrast grating, and a metasurface.

In still yet another embodiment, the first filter component includes a stack of layers having alternating high/low refractive indices.

In a still yet further embodiment, the stack of layers includes a polymer selected from the group consisting of: poly(2-chlorostyrene), poly(4-methoxystyrene), polysulfone resin, poly(styrene sulfide), poly(tetrafluoroethylene), poly(trifluorovinyl acetate), poly(chlorotrifluoroethylene), and poly(dimethyl siloxane).

In still another additional embodiment, the stack of layers includes a dielectric selected from the group of: TiO2, Ta2O5, Si3N4, SiO2, and Na3AlF6.

In a still further additional embodiment, the grid pattern includes a square pattern or a hexagonal pattern.

In still another embodiment again, the photovoltaic cells are even spaced apart in the grid pattern.

In a still further embodiment again, the waveguide layer includes a light coupling surface configured to couple incident light, each of the plurality of photovoltaic cells includes a first surface and a second surface, wherein the first surface has a larger area than the second surface, and each of the plurality of photovoltaic cells is oriented such that the first surfaces are at an angle relative to the light coupling surface of the waveguide layer.

In yet another additional embodiment, the first surfaces are perpendicular to the light coupling surface of the waveguide layer.

In a yet further additional embodiment, the luminescent solar concentrator has AM1.5G solar power conversion efficiencies of greater than 8%.

In yet another embodiment again, the luminescent solar concentrator has a transparency value of greater than 50%.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description will be more fully understood with reference to the following figures and data graphs, which are presented as exemplary embodiments of the invention and should not be construed as a complete recitation of the scope of the invention.

FIG. 1A conceptually illustrates an exploded view of an LSC in accordance with an embodiment of the invention.

FIG. 1B conceptually illustrates a profile view of an LSC in accordance with an embodiment of the invention.

FIG. 2 conceptually illustrates a waveguide layer with an inset showing a grid of interconnected micro-solar cells in accordance with an embodiment of the invention.

FIG. 3 conceptually illustrates various interconnection schemes and micro-solar cell orientations in accordance with various embodiments of the invention.

FIG. 4 conceptually illustrates a flow chart of a fabrication process for an LSC in accordance with an embodiment of the invention.

FIG. 5 conceptually illustrates an example spectrum of various components of an LSC and incident light with respect to wavelength in accordance with an embodiment of the invention.

FIGS. 6A and 6B show simulated performance of an LSC in accordance with an embodiment of the invention.

### DETAILED DESCRIPTION

Luminescent solar concentrators in accordance with various embodiments of the invention can be utilized for many different applications, including but not limited to transparent and semi-transparent photovoltaic applications. For example, an LSC can be implemented in a solar power window capable of harvesting light for energy conversion. Current state-of-the-art luminescent solar concentrators manufactured for power window markets orient the PV component as an edge-lining structure. In such structures, increasing window area results in an increase in average light travel lengths, which reduces the power conversion efficiencies (PCEs) of the window. LSCs in accordance with various embodiments of the invention can be configured to maintain constant light travel lengths within the waveguide by employing a grid of PV cells that are separated by a certain distance, which can also be termed as the geometric gain. Utilizing such structures, the window area can be scalable without an accompanying reduction in PCEs.

Luminescent solar concentrators having a grid-based PV design can be implemented in many different ways. In some embodiments, the LSC includes an optical waveguide, luminophores suspended in a polymer matrix, and a photovoltaic material. In several embodiments, the LSC is implemented using infrared luminophore technology combined with a PV design implementing a grid of PV cells. LSCs can incorporate quantum dots (QDs) that absorb uniformly across the visible spectrum and photoluminesce down-shifted energy light in the infrared wavelength regime. In a number of embodiments, a power-generating window LSC architecture employing highly efficient InAs/InP/ZnSe quantum dots for uniform isotropic light absorption across the visible spectrum and infrared photoluminescence (PL) is implemented. Some embodiments include PV cells utilizing micro-grid structures that can be implemented for scalable and controllably transparent applications, such as but not limited to power windows targeted for building integrated photovoltaic (BIPV) applications. The LSC can be designed to concentrate light onto the grid structures, which can be implemented using various PV materials including but not limited to small Si solar cells. In a number of embodiments, the LSCs can utilize a unique PV cell form factor and spectral filter coatings to increase the thermal insulation of the window and enhance photocurrent capture by a silicon micro-grid. In further embodiments, the LSC can include two short-pass polymeric filters that enable LSC PL light-trapping and also low-emissivity window thermal insulation performance. LSCs, related methods of fabrication, and experimental results are discussed below in further detail.

### Micro-Grid Luminescent Solar Concentrators and Related Applications

Luminescent solar concentrators in accordance with various embodiments of the invention can be utilized for a number of different applications. In some embodiments, the LSC includes a PV material having a micro-grid design. Such implementations can be utilized in transparent or semi-transparent applications such as but not limited to power-producing windows for use in building and engineering applications. By utilizing a micro-grid design instead of the traditional edge-lined PV material, the LSC is scalable to different window areas and can be capable of operating with a power conversion efficiency of greater than 8% under diffuse lighting conditions. In some embodiments, the power-producing window can be implemented with different opacities. The window can also be implemented to have an opacity that varies by electronic control. For example, such implementations can have windows with different opacity states for different conditions, such as a state for increased light absorption and electrical generation, a state for transparency, and intermediate states with some level of opacity for a hazy effect. As can readily be appreciated, the specific LSC implementation, including but not limited to opacity configurations can depend on the specific requirements of a given application. LSC architectures and configurations are described below in further detail.

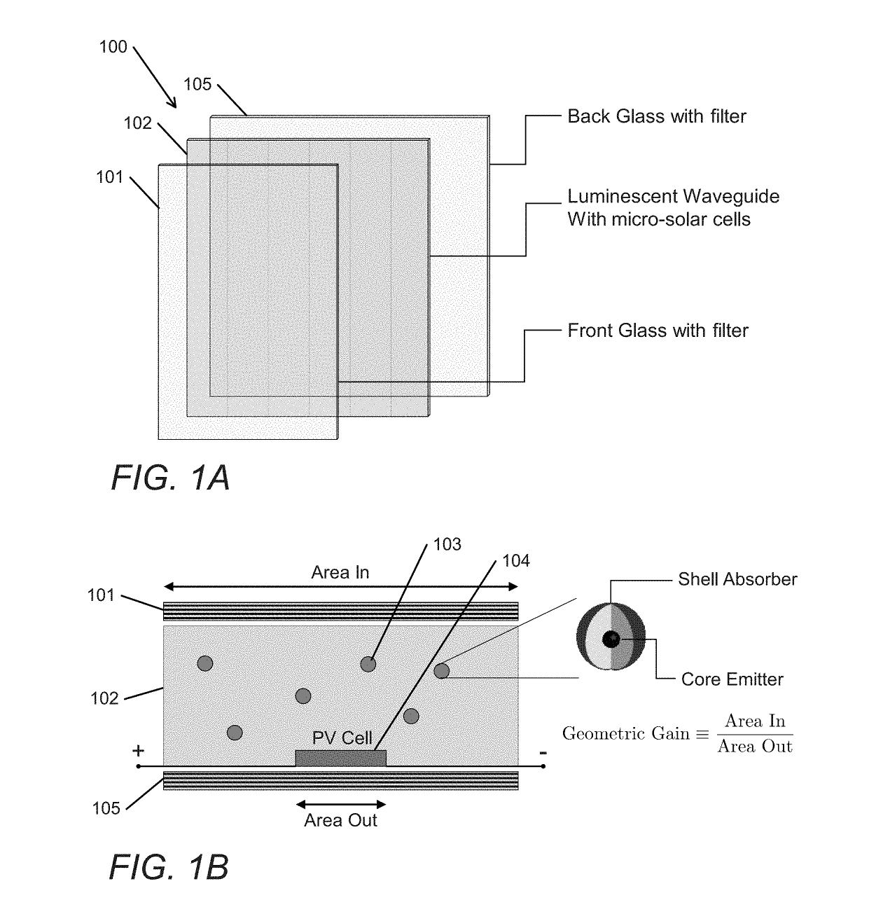

LSC architectures, including but not limited to power-generating window implementations, can utilize various materials and components to provide an area-scalable form factor capable of high PCEs. In some embodiments, an LSC is configured to include an optical waveguide, luminophores, and a photovoltaic material. In further embodiments, the LSC can include filters on either side of the optical waveguide for the trapping of light within a predetermined wavelength range. FIGS. 1A and 1B conceptually illustrate an exploded view and a profile view, respectively, of an LSC in accordance with an embodiment of the invention. As shown, the LSC 100 includes a front glass 101 with a filter on the back, a luminescent waveguide 102 with embedded luminophores 103 and embedded and electrically interconnected micro-solar cells 104 that are arranged in a grid pattern, and a back glass 105 with a filter on the front. Such filter components can include but are not limited to polymeric mirrors and reflectance films.

In a significant departure from traditional LSC designs, LSCs in accordance with various embodiments of the invention can incorporate PV cells arranged in a micro-grid fashion. In applications where transparency is desired (such as a power-generating window), spacing between the cells can influence the transparency levels. Various PV cells, such as but not limited to Si solar cells, can be utilized. The Si cells can be fabricated by customizing small cells singulated from commercially available cells, including but to limited to passivated emitter rear contact (PERC) solar cells and interdigitated back contact cells. In some embodiments, the LSC employs QD luminophores that are spectrally-matched to Si photovoltaic micro-cells that are arranged in a sparse areal density micro-cell array. Using such components in a flexibly area-scalable array form factor, the LSC can reach power efficiencies extending beyond 8% with controllable opacity and color (no undesirable color tint). Different types and sizes of PV cells can be utilized. In many embodiments, a single cell has an area of less than 1 mm². PV cells can be interconnected as an array to form the micro-grid. The interconnection process can include a variety of methods, including but not limited to electroplating, sputtering, and screen printing. Additionally, various materials, such as but not limited to Au, Ag, Cu, Al, and chrome can be utilized in the interconnection process.

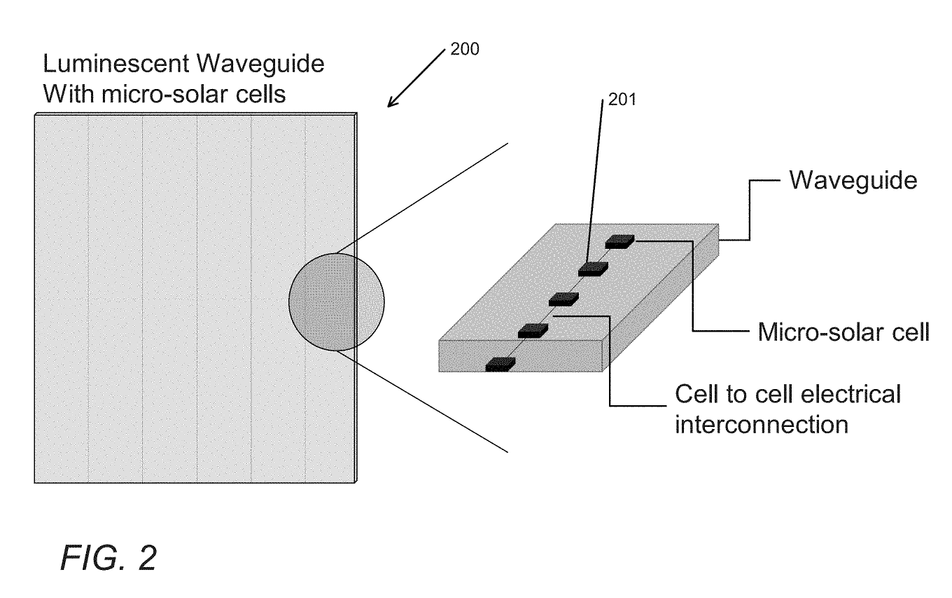

FIG. 2 conceptually illustrates a waveguide layer with an inset showing a grid of interconnected micro-solar cells in accordance with an embodiment of the invention. As shown, the waveguide 200 are embedded with an array of micro-solar cells 201. The micro-solar cells 201 are electrically interconnected. In the illustrative embodiment, the cells are oriented in a planar fashion and interconnected in a direct line. As noted above, the distance between any two micro-solar cells can vary depending on the specific requirements of a given application. Although FIGS. 1A, 1B, and 2 show specific LSCs, various configurations and designs can be implemented as appropriate depending on the specific requirements of a given application. Various interconnection schemes and grid placement could be utilized.

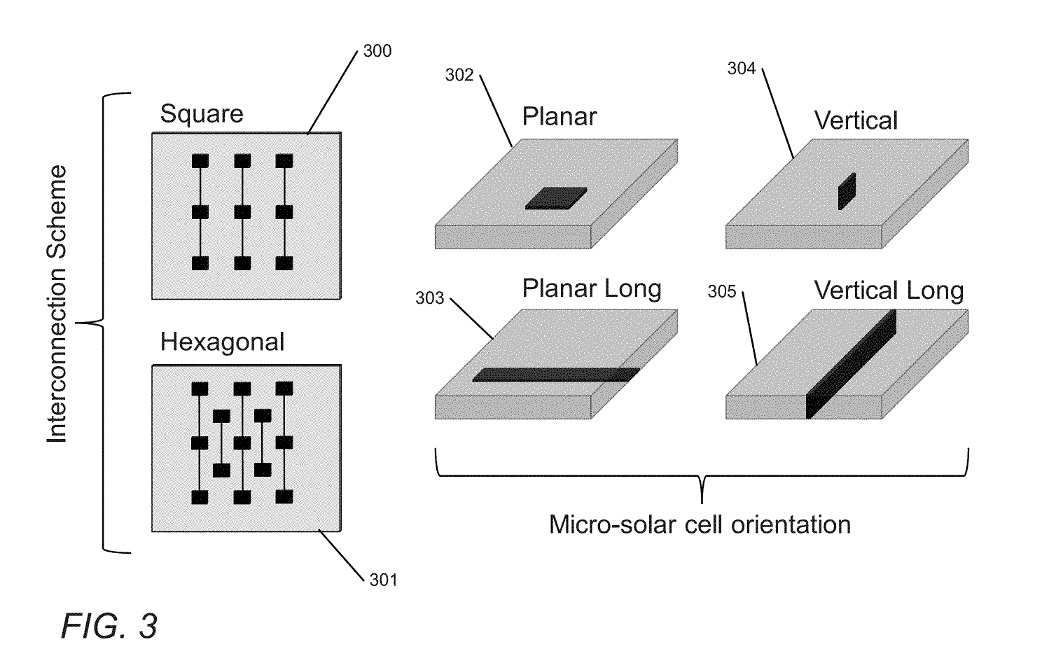

The electrical lines connecting the cells also include a variety of designs. For example, in some embodiments, the rows of cells are electrically connected in series and the columns across cells can be connected in parallel. Various grid geometries, such as but not limited to square and hexagonal patterns, can be utilized. Additionally, the micro-solar cells' orientations can also differ from application to application. FIG. 3 conceptually illustrates various interconnection schemes and micro-solar cell orientations in accordance with various embodiments of the invention. As shown, the different types of interconnection schemes can include a square pattern 300 and a hexagonal pattern 301. Also, the micro-cell can be oriented in a variety of different ways, including but not limited to planar 302, planar long 303, vertical 304, and vertical long 305. Although FIG. 3 illustrates specific interconnection schemes and micro-solar cell orientation, any configuration and design can be utilized as appropriate depending on the specific requirements of the given application. For example, different geometric patterns can be utilized instead of a square or hexagonal pattern.

The luminophores utilized in LSCs in accordance with various embodiments of the invention can vary widely in composition and configuration. For example, in a number of embodiments, the luminophores are embedded in a polymer that constitutes the optical waveguide. In several embodiments, infrared luminophore technology is utilized. Such luminophores can include QDs having a core-shell structure for absorbing and radiating light. In a number of embodiments, the luminophores have a core with a bandgap in the infrared regime. In several embodiments, luminophores with a radiative efficiency of greater than 80% are utilized. In some embodiments, quantum dots, such as but not limited to InAs/InP/ZnSe QDs, are utilized as the luminophores. Highly efficient InAs/InP/ZnSe QDs can allow for uniform isotropic light absorption across the visible spectrum and infrared photoluminescence (PL). As can readily be appreciated, the choice of luminophores can depend on the specific requirements of a given application. For example, it can be desirable to implement a power-generating window without color tinting. Luminophores that absorb uniformly across the visible spectrum can be chosen for such applications. Luminophores that absorb uniformly across a spectral range can be chosen based on a low relative percent change (such as around 30%) over the range. In many embodiments, the luminophores utilized emits light in the infrared regime and has a light absorption of greater than 40% of the amount of light between 400 nm and 700 nm. LSCs can be configured to concentrate light, including photoluminesced light from luminophores, onto the PV material. In several embodiments, the luminophores are dispersed within a polymeric waveguide layer. Varying the concentration of QD luminophores within the waveguide layer can allow for the implementation of a power window with a visible transparency that can be controllably tuned. The waveguide layer can range in thickness. In some embodiments, the waveguide layer is approximately 100 micrometers in thickness. Such a polymer waveguide can be made via common polymer materials (e.g. EVA, PMMA, PDMS, PLMA).

Light re-emitted by QDs can be directed towards all directions. In many embodiments, the QD-polymer LSC can be encased with short-pass filters, which allows for the trapping of the photoluminescence generated by the luminophores within the waveguide. For example, some embodiments include coating the top and bottom surfaces of the LSCs with polymeric filters that are designed to reflect a specific wavelength range. In some embodiments, spectrally-selective multilayer polymeric mirrors are utilized for the trapping of the photoluminescence within the waveguide. In a number of embodiments, reflectance films are utilized as filters for trapping light within the waveguide.

### Fabrication of LSCs

LSCs in accordance with various embodiments of the invention can incorporate an array of micro-sized solar cells to collect light for conversion into electrical power. Such grids can be printed with a predetermined amount of spacing between adjacent cells. The electrical lines connecting the cells also include a variety of designs. For example, in some embodiments, the rows of cells are electrically connected in series and the columns across cells can be connected in parallel. Fabrication processes for grids of micro-sized solar cells in accordance with various embodiments of the invention can include many different techniques. For example, in some embodiments, micro-sized solar cells are fabricated by precise laser cutting of large-area solar cells. In several embodiments, such cells are fabricated through wet or dry etching of large-area solar cell wafers along with post-processing steps. Various classes of materials can be considered for the solar cell device. Such cells can include but are not limited to passivated emitter rear contact (PERC) cells, heterojunction with intrinsic thin layer (HIT) Si cells, passivated contact Si cells, GaAs cells, and InGaP cells. As can readily be appreciated, the type of materials utilized can depend on the specific requirements of a given application. Additionally, micro-sized solar cells can have different dimensions. In some embodiments, the solar cell has dimensions of less than 1000 micrometers. In several embodiments, the solar cell has one dimension that is less than 1000 micrometers. As can readily be appreciated, the sizes and dimensions of the solar cells can vary widely. For example, in applications where transparency is not as critical, the solar cells can have larger dimensions.

Once the micro-sized cell is fabricated and processed, the cells can be assembled into a grid pattern. Various grid geometries, such as but not limited to square and hexagonal patterns, can be utilized. Techniques for assembling cells can include pick-and-place printing technology and micro-transfer printing technology. The assembled grid of cells can then be electrically interconnected using any process, such as but not limited to screen printing, sputtering, thermal evaporation, and pick-and-place lining. As discussed above, such electrical lines can be designed to interconnect the cells in many different ways. Additionally, various interconnection materials, such as but not limited to Au, Ag, Al, Cu, and chrome, can be utilized.

LSCs in accordance with various embodiments of the invention utilizes a waveguide for receiving, trapping, and/or redirecting incoming light for the purposes of energy conversion. The waveguide can also provide luminophore-generated light a means to travel to and be collected by the solar cells. Waveguides in LSCs can have varying thicknesses as well as varying concentrations of luminophores. In many embodiments, the waveguide is transparent. In such embodiments, the concentration of the luminophores can determine the overall transparency of the LSC. Additionally, luminophores that re-emit light in an infrared spectral range can be utilized for transparent applications as the infrared light will not affect transparency. The waveguide layer can be formed by depositing a liquid polymer material directly atop a micro-cell grid (such as those described above) for direct optical contact. Final waveguide layer thickness can be selected using any of a number of different techniques, such as but not limited to doctor-blading and spin-coating at specific speeds. Once the polymer material solidifies/cures, the waveguide layer is formed. Luminophore materials can be dispersed within the waveguide material before deposition onto the micro-cell grid. Various types of materials can be utilized as the waveguide material, including but not limited to poly(lauryl methacrylate) (PLMA), poly(methyl methacrylate) (PMMA), polydimethylsiloxane (PDMS), and polymides (PI).

A luminophore can be described as a small (often nanometer-sized) particle that can directly interact with incident light. The luminophores can absorb light across a certain energy range and re-radiate the light at a certain lower energy range. The range of absorbed and emitted light can be tunable as well as the energy separation between the two. As discussed above, luminophores can be dispersed within the waveguide at a certain concentration to absorb a certain percentage of incident light and, thereby, determining the overall transparency. Luminophores can be synthesized in a number of methods, which can depend on the specific type of luminophores to be formed. For example, core/shell quantum dot luminophores made of semiconducting materials (e.g., CdSe/CdS core/shell) can be synthesized colloidally. As can readily be appreciated, the type of luminophores utilized can depend on the specific requirements of a given application. In many embodiments, the luminophores are chosen for their spectral range of absorption and emission. Depending on the application, such ranges can be tuned for greater results. Examples of luminophores can include but are not limited to InAs/InP/ZnSe core/shell/shell quantum dots, CdSe/CdS core/shell quantum dots, and CuInS₂/ZnS core/shell quantum dots.

An LSC can also include filters that optically encase the waveguide/micro grid components. The filter can be chosen to exhibit high reflectance in the emission range of the chosen luminophores, thereby trapping a percentage of light emitted by the luminophores. In some embodiments, the filter exhibits high reflectance in the near infrared and infrared regions of the spectrum, providing thermal efficiency to the LSC application. In many embodiments, the filter exhibits more than 99% reflectance in the emission range of the luminophores. In some embodiments, the filter exhibits more than 99% reflectance in the near-infrared and infrared range. In order to allow for high power efficiency, the filter can also exhibit high transmittance in the luminophore absorption range in order to increase the amount of light reaching the luminophores. Additionally, this can also allow for transparency requirements of some applications, such as but not limited to functioning as a window component. The fabrication process for filters with such reflectance properties can vary widely depending on the choice of material. For polymeric filters, thin stacks of alternating high/low refractive index material can be formed using various processes, such as but not limited to polymer extrusion. For dielectric filters, the thin stacks of high/low refractive index material can be formed via a variety of deposition methods including but not limited to sputtering, electron-beam, and thermal evaporation. Other filter designs can include but are not limited to high contrast gratings and metasurfaces. As can readily be appreciated, the implementation of a filter component can be achieved using many different designs. Material candidates for the filter component can include but are not limited to polymers, dielectrics, and various other materials. For example, polymers that can be utilized to form filters in accordance with various embodiments of the invention can include high index polymers (such as but not limited to poly(2-chlorostyrene), poly(4-methoxystyrene), polysulfone resin, and poly(styrene sulfide)) and low index polymers (such as but not limited to poly(tetrafluoroethylene), poly(trifluorovinyl acetate), poly(chlorotrifluoroethylene), and poly(dimethyl siloxane). Dielectric materials can include high index dielectrics (such as but not limited to TiO₂, Ta₂O₅, and Si₃N₄) and low index dielectrics (such as but not limited to SiO₂ and Na₃AlF₆).

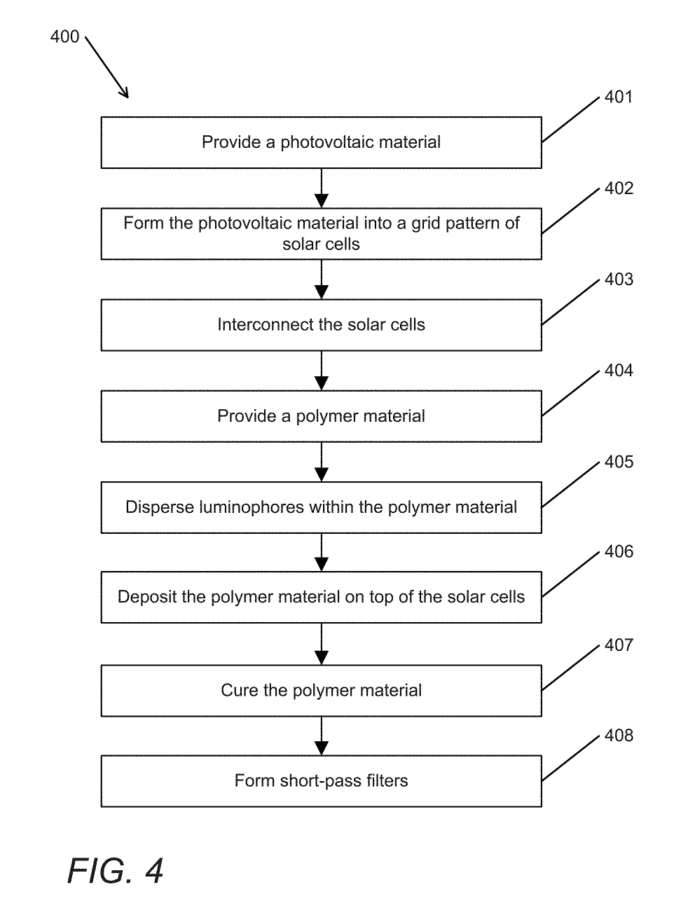

Although specific methods of fabrication are discussed above, different combinations, omissions, and additions of steps can be utilized to manufacture an LSC. FIG. 4 conceptually illustrates a flow chart of a fabrication process for an LSC in accordance with an embodiment of the invention. The process 400 can start with providing (401) a PV material. The PV material can be formed (402) into a grid pattern of solar cells using any of the various processes described above. The formation process can be performed using various techniques. In some embodiments, the PV material is diced into smaller cells, which can then be printed into a grid pattern. The grid pattern of solar cells can be interconnected (403) utilizing a variety of different processes, such as those described above. A polymer material can be provided (404) for the purposes of forming a waveguide layer. Luminophores can be dispersed (405) within the polymer material. The polymer material can be deposited (406) on top of the solar cells, encasing them. Once the polymer material solidifies/cures (407), a short-pass filter can be formed (408) on each side of the device. As can readily be appreciated, FIG. 4 describes only one specific method of fabricating an LSC. Various other techniques and methods can be utilized as appropriate depending on the specific requirements of a given application.

### Simulations, Measurements, and Manufacturing Costs Analysis

LSCs in accordance with various embodiments of the invention can be implemented for a variety of different applications. Depending on the application, the LSC can be configured to provide different functionalities. For example, energy-efficient buildings can be equipped with LSC power windows that can be configured with various capabilities, such as but not limited to providing for daylighting, enabling a flexible choice of colors (including transparent, grey, and RGB values), managing thermal radiation to improve thermal efficiency, and generating significant quantities of electrical power. In such applications, LSCs in accordance with many embodiments of the invention can have manufacturing costs that are equal to or less than doubled-glazed windows. LSCs absorb and concentrate light in window-like planar sheet waveguides, and can be used to form a low-profile concentrating photovoltaic module for both direct and diffuse sunlight. Traditional LSCs have exhibited low power conversion efficiency, limited durability, and have employed chromophores that limit the window color and transparency to certain colors (e.g., orange or yellow).

Many embodiments of the invention are directed towards visible-transparent LSC photovoltaic power windows that enable (i) transparency values ranging from 5%-90%, (ii) one sun, AM1.5G solar PCEs of >8%, (iii) a wide choice of window color, including neutral-density (gray), rather than the limited colors (e.g., orange/yellow) seen in previous windows, and (iv) a micro-printed cell array architecture enabling the geometric gain and concentration of the LSC to be adjustable, independent of the window area. Initial economic modeling suggests such LSC power windows can be manufactured for less than $110/m², which is less than the cost of reasonable quality, conventional Ar-filled double-glazed low-E windows.

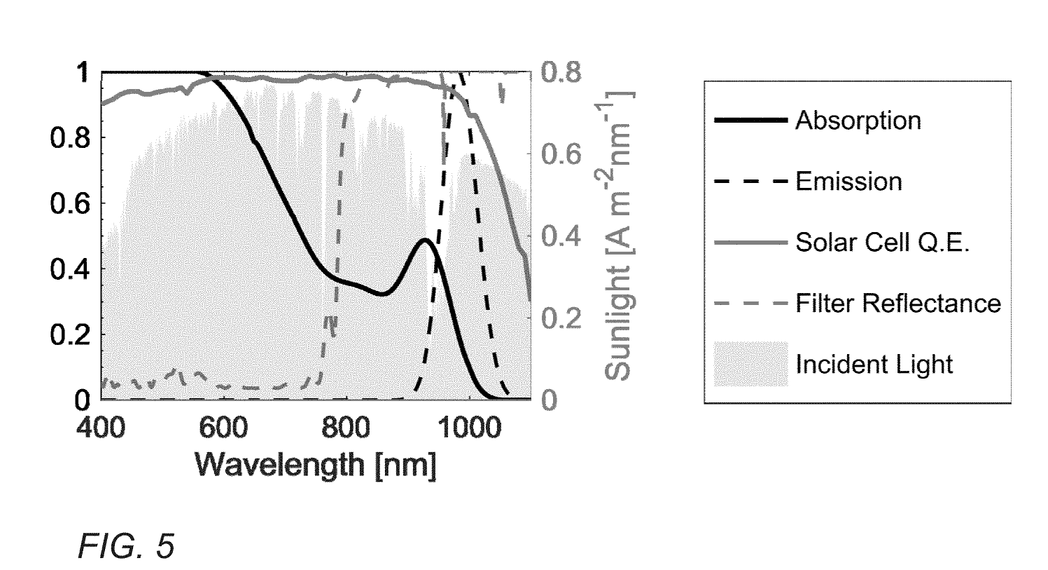

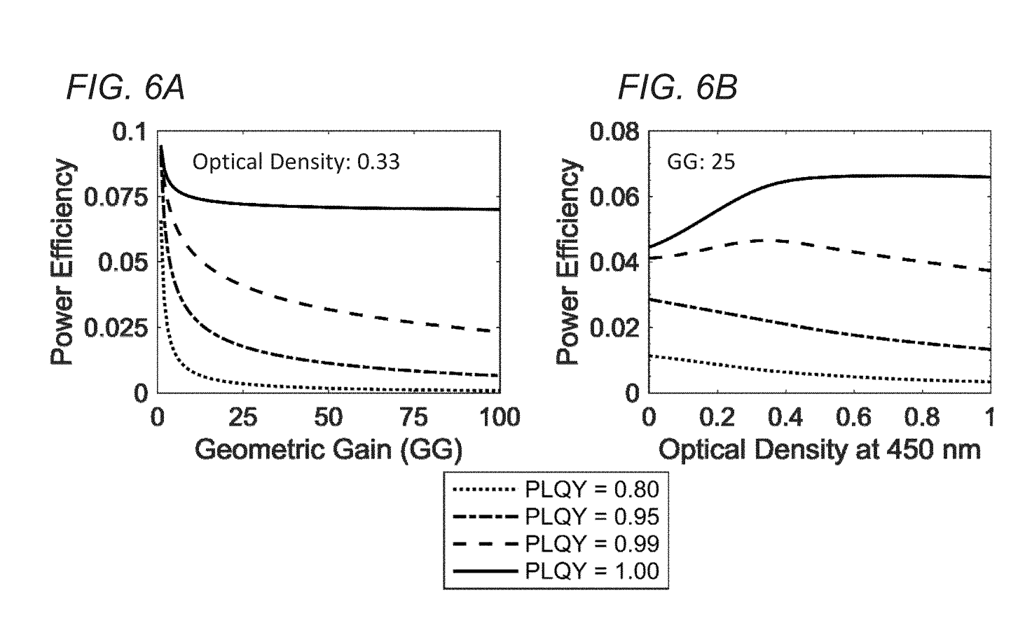

The potential PCE and transparency of an LSC window in accordance with various embodiments of the invention can be analyzed using a validated, Monte Carlo ray-trace LSC modeling tool. FIG. 5 conceptually illustrates an example spectrum of various components of an LSC and incident light with respect to wavelength in accordance with an embodiment of the invention. As shown in FIG. 5, InAs/InP/ZnSe QDs absorb uniformly across the visible spectrum and emit photons isotropically in the near-infrared wavelength regime, with measured photoluminescence quantum yields (PLQYs) above 80%. For: absorption and emission, the units are arbitrary units (a.u); for solar cell Q.E., the units are fractional quantum efficiency; for filter reflectance, the units are fractional percent reflected); and for incident light, the units correspond to the right y-axis (given in Amps per meter sq. per nanometer). In operation, daylight can be absorbed by the quantum dots and re-radiated as photoluminescence. The PL can be trapped in a polymer waveguide layer encapsulated by short-pass optical filters. To achieve high optical efficiency, an array of Si micro-cells at a fixed geometric gain can be embedded within the waveguide. Higher optical densities (OD) of suspended QD luminophores can create a less transparent window with higher power conversion efficiencies, while lower OD gives a more transparent, lower PCE window. FIGS. 6A and 6B show the performance of an LSC in accordance with an embodiment of the invention. FIGS. 6A and 6B shows the power efficiency of the LSC with varying geometric gains, optical densities at 450 nm, and photoluminescence quantum yields. Geometric gain can be defined as the ratio of total window area to total micro-solar cell area. The optical density of the window gives how much light can pass through the full window, and the PLQY of the luminophores which gives the overall efficiency of how the luminophore absorbs and emits light.

The bill of materials for an LSC in accordance with various embodiments of the invention can include glass, polymeric short-pass filter coatings, polymer waveguide materials, quantum dot materials, Si micro-cells singulated from commercial wafers, and interconnection costs. Standard float glass window panels with a cost of ˜$38/m² can be used. In several embodiments, one panel supports the bottom polymeric filter and LSC waveguide, and the other glass panel supports the polymeric top filter coating. Polymeric filters have a cost of ˜$1.30/m². The cost of the PLMA waveguide with embedded interconnects and micro-cell processing can be estimated to be ˜$10.10/m². The cost of quantum dots using known synthesis procedures for CdSe/CdS can depend on the desired concentration. In some embodiments, the desired concentration of CdSe/CdS quantum dots can cost ˜$13/m² to manufacture. Customized Si PERC cell cost is ˜$100/m². In many embodiments, the LSC design utilizes a geometric gain of 25 and only 4% of the area is covered by the Si micro-cells. Thus, a cell cost of ˜$4/m² is applicable for such embodiments. Given these device materials and processing costs, a total module expense is estimated to be ˜$105.70/m², which is less than half the cost of standard double glazed windows ($250/m²). As can readily be appreciated, the costs depend greatly on the design implemented, which can vary depending on the specific requirements of a given application. For example, different LSC designs in accordance with various embodiments of the invention can employ different geometric gains, which can affect the costs of manufacturing.

### Doctrine of Equivalents

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A luminescent solar concentrator comprising:
a waveguide layer configured to couple incident light;
a plurality of luminophores configured to absorb incident light and emit infrared light within the waveguide layer;
a plurality of photovoltaic cells configured to convert incident light traveling within the waveguide into a voltage signal, wherein the photovoltaic cells are interconnected in a grid pattern.

2. The luminescent solar concentrator of claim 1, wherein each of the plurality of photovoltaic cells has dimensions of less than 1000 micrometers.

3. The luminescent solar concentrator of claim 1, wherein the plurality of luminophores is configured to absorb greater than 40% of the amount of light having wavelengths between 400 nm and 700 nm.

4. The luminescent solar concentrator of claim 1, wherein the waveguide layer comprises a material selected from the group consisting of: poly(lauryl methacrylate), poly(methyl methacrylate, polydimethylsiloxane, and polymides.

5. The luminescent solar concentrator of claim 1, wherein the plurality of luminophores comprises a plurality of quantum dots.

6. The luminescent solar concentrator of claim 5, wherein each of the plurality of quantum dots comprises a core/shell structure.

7. The luminescent solar concentrator of claim 1, wherein the plurality of luminophores comprises a quantum dot selected from the group consisting of: an InAs/InP/ZnSe quantum dot, a CdSe/CdS quantum dot, and a CuInS₂/ZnS quantum dot.

8. The luminescent solar concentrator of claim 1, wherein the plurality of photovoltaic cells comprises a photovoltaic cell selected from the group consisting of: a passivated emitter rear contact cell, a heterojunction with intrinsic thin layer Si cell, a passivated contact Si cell, GaAs cell, and InGaP cell.

9. The luminescent solar concentrator of claim 1, wherein the plurality of photovoltaic cells is interconnected with a material selected from the group consisting of: Au, Ag, Cu, Al, and chrome.

10. The luminescent solar concentrator of claim 1, further comprising:
a first filter component disposed on a first side of the waveguide layer; and
a second filter component disposed on a second side of the waveguide layer.

11. The luminescent solar concentrator of claim 10, wherein the first filter component comprises a filter selected from the group consisting of: a high-pass filter, a high-contrast grating; and a metasurface.

12. The luminescent solar concentrator of claim 10, wherein the first filter component comprises a stack of layers having alternating high/low refractive indices.

13. The luminescent solar concentrator of claim 12, wherein the stack of layers comprises a polymer selected from the group consisting of: poly(2-chlorostyrene), poly(4-methoxystyrene), polysulfone resin, poly(styrene sulfide), poly(tetrafluoroethylene), poly(trifluorovinyl acetate), poly(chlorotrifluoroethylene), and poly(dimethyl siloxane).

14. The luminescent solar concentrator of claim 12 wherein the stack of layers comprises a dielectric selected from the group consisting of: TiO₂, Ta₂O₅, Si₃N₄, SiO₂, and Na₃AlF₆.

15. The luminescent solar concentrator of claim 1, wherein the grid pattern comprises a square pattern or a hexagonal pattern.

16. The luminescent solar concentrator of claim 1, wherein the photovoltaic cells are even spaced apart in the grid pattern.

17. The luminescent solar concentrator of claim 1, wherein:
the waveguide layer comprises a light coupling surface configured to couple incident light;
each of the plurality of photovoltaic cells comprises a first surface and a second surface, wherein the first surface has a larger area than the second surface; and
each of the plurality of photovoltaic cells is oriented such that the first surfaces are at an angle relative to the light coupling surface of the waveguide layer.

18. The luminescent solar concentrator of claim 17, wherein the first surfaces are perpendicular to the light coupling surface of the waveguide layer.

19. The luminescent solar concentrator of claim 1, wherein the luminescent solar concentrator has AM1.5G solar power conversion efficiencies of greater than 8%.

20. The luminescent solar concentrator of claim 1, wherein the luminescent solar concentrator has a transparency value of greater than 50%.
